(19) United States
(12) Patent Application Publication
(10) Pub. No.: US 2009/0314212 A1
(43) Pub. Date: Dec. 24, 2009

(54) VACUUM VAPOR-DEPOSITION APPARATUS

(75) Inventor: CHUNG-PEI WANG, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/481,588

(22) Filed: Jun. 10, 2009

(30) Foreign Application Priority Data
Jun. 19, 2008 (CN) 200810302231.2

(51) Int. Cl. C23C 16/00

(52) U.S. Cl. 118/730

(57) ABSTRACT

A vacuum vapor-deposition apparatus is configured for coating a plurality of substrates, and includes a motor including a rotating shaft, a supporting member, a connecting ring, and a vapor source. The rotating shaft includes a first plate fixedly mounted to an end surface of the rotating shaft. The supporting member includes a second plate corresponding to the first plate and is configured for mounting the plurality of substrates thereon. The connecting ring defines a groove along an inner circumference of the connecting ring, and includes a first semi-ring and a second semi-ring fastened to the first semi-ring. The first plate and the second plate are non-rotatably received in the groove. The first plate and the second plate are disengageable from the groove if the first and second semi-rings are unfastened. The vapor source is configured for producing evaporated material to be deposited on the substrates.

### BACKGROUND

1. Technical Field

The present disclosure relates to coating technology, and particularly to a vacuum vapor-deposition apparatus.

2. Description of Related Art

Generally, a vacuum vapor-deposition apparatus for coating a plurality of optical substrates such as plastic lenses, includes a vacuum container, a vapor source for producing evaporated material, and a supporting member for mounting the plurality of optical substrates to be coated by the evaporated material. The vapor source is positioned in the lower portion of the vacuum container. The supporting member is fixed to a rotating shaft located in the upper portion of the vacuum container via screws. However, using the screws to assemble the supporting member to the rotating shaft is a time-consuming work.

Therefore, what is needed is to provide a vacuum vapor-deposition apparatus, which can overcome the above-mentioned problem.

### BRIEF DESCRIPTION OF THE DRAWINGS

FIG. 1 is a schematic, cross-sectional view of a vacuum vapor-deposition apparatus, according to a first exemplary embodiment.

FIG. 2 is a partially, enlarged isometric view of the vacuum vapor-deposition apparatus of FIG. 1.

FIG. 3 is an exploded, isometric view of the vacuum vapor-deposition apparatus of FIG. 2.

FIG. 4 is a partially exploded isometric view of the vacuum vapor-deposition apparatus, according to a second exemplary embodiment.

FIG. 5 is a partially exploded isometric view of the vacuum vapor-deposition apparatus, according to a third exemplary embodiment.

FIG. 6 is a partially exploded isometric view of the vacuum vapor-deposition apparatus, according to a fourth exemplary embodiment.

### DETAILED DESCRIPTION

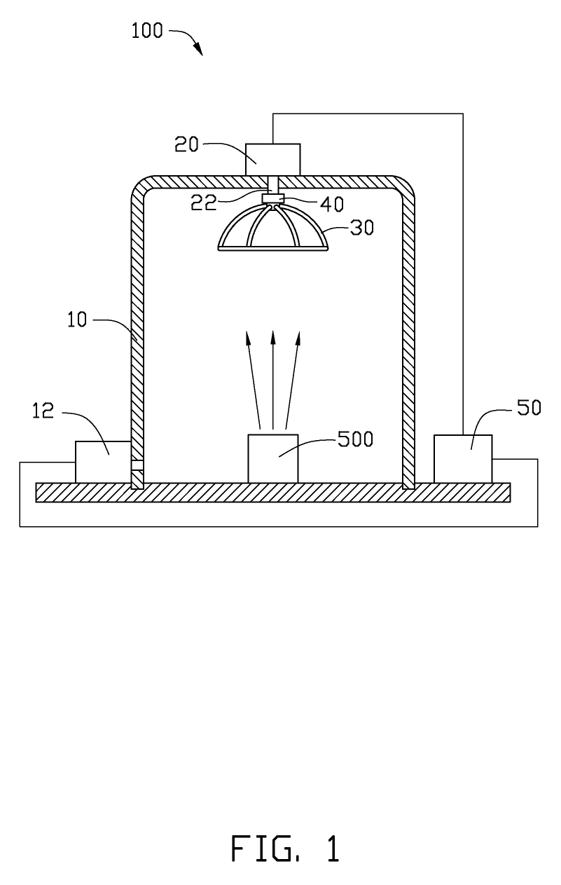

Referring to FIG. 1, a vacuum vapor-deposition apparatus 100 for coating a plurality of substrates (not shown) with a vapor source 500, according to a first exemplary embodiment, includes a vacuum container 10, a motor 20 including a rotating shaft 22, an umbrella-like supporting member 30, a connecting ring 40 for connecting the supporting member 30 to the rotating shaft 22, and a controller 50.

The vacuum container 10 is vacuumized by a vacuum pump 12 positioned outside the vacuum container 10. The vapor source 500 is positioned on the bottom of the vacuum container 10 and is configured for producing evaporated material to be deposited on the plurality of substrates (not shown). The controller 50 is electrically connected to the vacuum pump 12 and the motor 20. The controller 50 is configured for controlling the motor 20 and the vacuum pump 12.

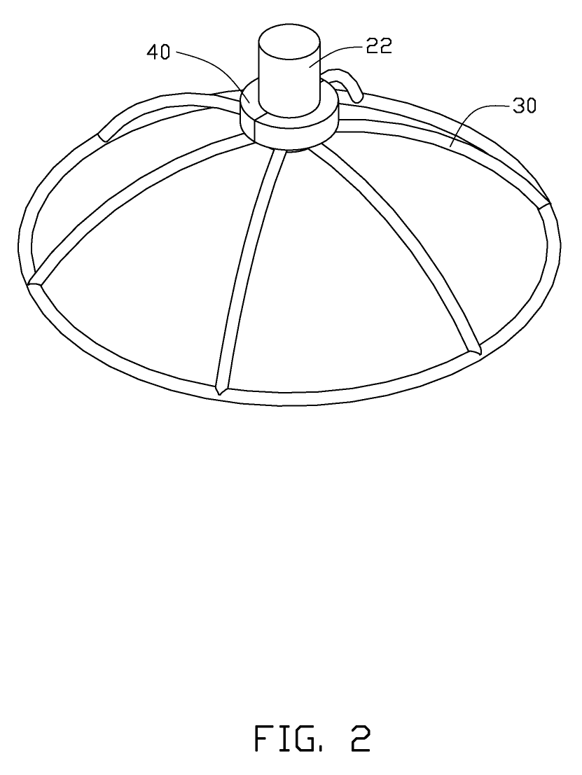

Referring to FIGS. 1-3, the motor 20 is positioned on the top of the vacuum container 10 and the rotating shaft 22 extends through the vacuum container 10. The rotating shaft 22 includes a shaft body 220 and a first plate 222 fixed to an end surface 220a of the shaft body 220. The first plate 222 has an approximately polygonal cross-section. For example, the first plate 222 has an approximately uniform octagonal prism shape.

The supporting member 30 is configured for mounting the plurality of substrates (not shown) in openings 32 defined in the supporting member 30. The supporting member 30 includes an umbrella-like supporting body 34, a connecting body 36 positioned in the top center of the supporting body 34, and a second plate 38 fixed on an end surface 36a of the connecting body 36. The second plate 38 is shaped corresponding to the first plate 222. The umbrella-like supporting body 34 includes a plurality of spokes 342 radially extending from the connecting body 36, and an annular member 344. Each spoke 342 has a first end 342a attached to the connecting body 36 and an opposing second end 342b attached to the annular member 344.

A groove 40b is defined in the inner surface 40a of the connecting ring 40 along an inner circumference of the connecting ring 40. The shape of the groove 40b is shaped corresponding to the first plate 222 and the second plate 38. The connecting ring 40 includes a first semi-ring 42 and a second semi-ring 44. The first semi-ring 42 includes a first end 42a and a second end 42b. The second semi-ring 44 includes a third end 44a and a fourth end 44b. The first end 42a is jointed to the third end 44a by a hinge structure 46. Two magnets (not shown) are mounted to the second end 42b and the fourth end 44b respectively so that the second end 42b is attracted by the fourth end 44b.

The first plate 222, the second plate 38, and the groove 40b satisfy the following formula: (H₁+H₂)≦L, where H₁ is the thickness of the first plate 222, H₂ is the thickness of the second plate 38, and L is the width of the groove 40b. The first plate 222 and the second plate 38 are non-rotatably received in the groove 40b, and the second end 42b is attracted by the fourth end 44b so that the supporting member 30 is connected to the rotating shaft 22 and rotates together with the rotating shaft 22. Therefore, assembling the supporting member 30 to the rotating shaft 22 takes less time.

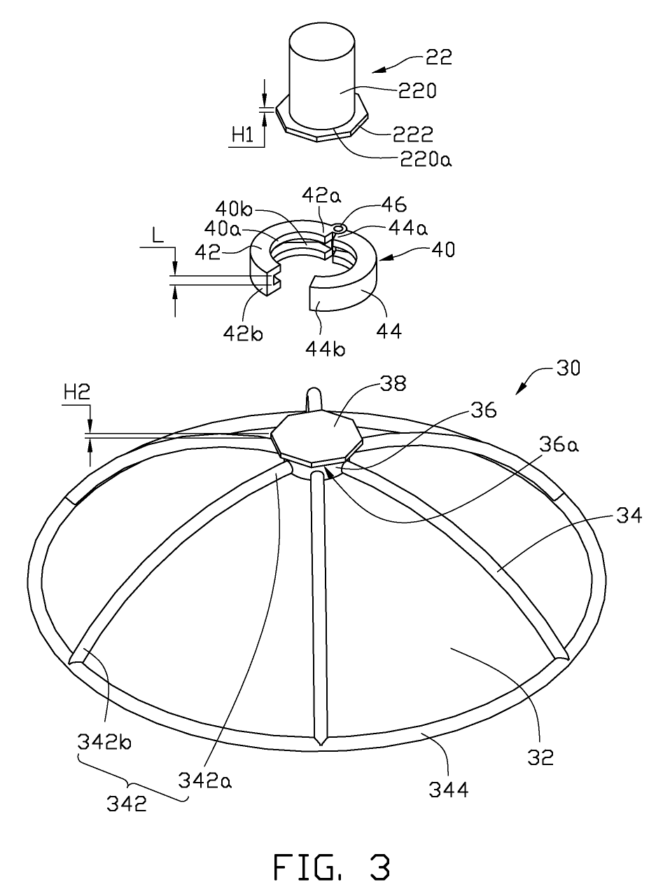

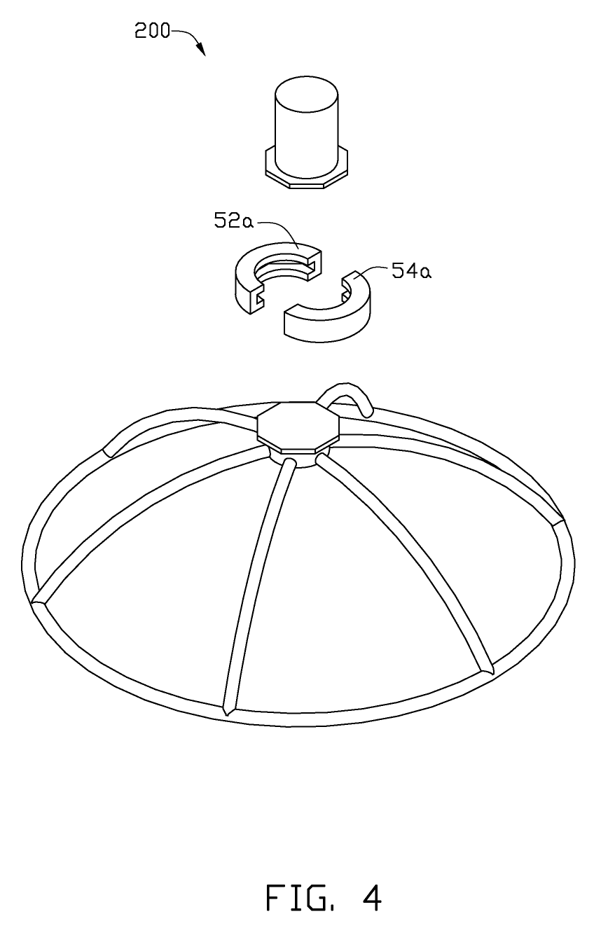

Referring to FIG. 4 together with FIG. 3, a vacuum vapor-deposition apparatus 200 according to a second exemplary embodiment is shown. The difference between the vacuum vapor-deposition apparatus 200 of this embodiment and the vacuum vapor-deposition apparatus 100 of the first embodiment are that the hinge structure 46 is omitted and two additional magnets (not shown) are mounted to the first end 52a and the third end 54a respectively so that the first end 52a is attracted by the third end 54a.

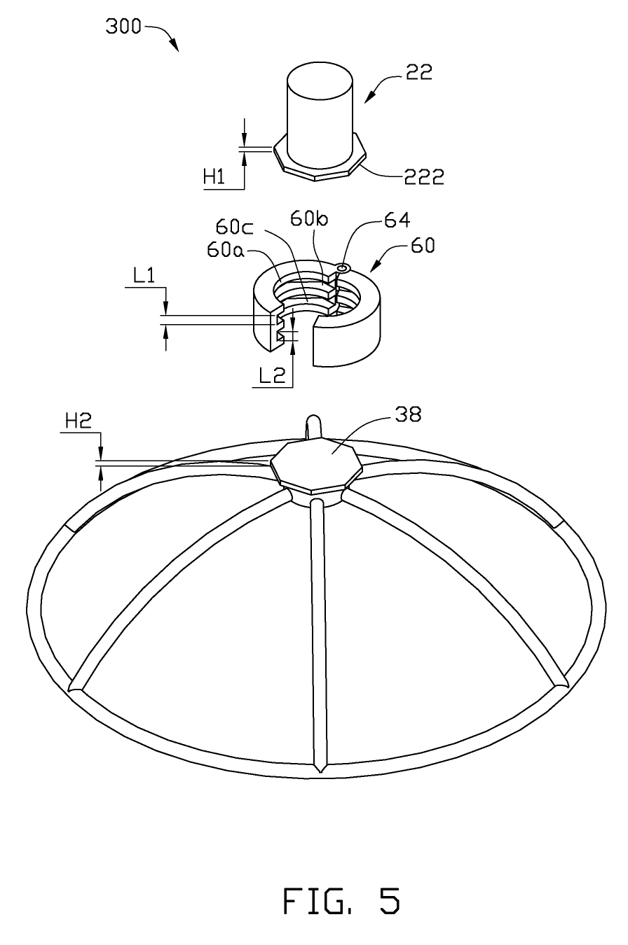

Referring to FIG. 5 together with FIG. 3, a vacuum vapor-deposition apparatus 300 according to a second exemplary embodiment is shown. The difference between the vacuum vapor-deposition apparatus 300 of this embodiment and the vacuum vapor-deposition apparatus 100 of the first embodiment are that a first groove 60b and a second groove 60c are defined in the inner surface 60a of the connecting ring 60 instead of one groove 40b. The shapes of the first groove 60b and the second groove 60c correspond to the first plate 222. The first plate 222 is non-rotatably received in the first groove 60b. The second plate 38 is non-rotatably received in the second groove 60c.

The first plate 222, the second plate 38, the first groove 60b, and the second groove 60c satisfy the following formulas: H1≦L1, H2≦L2, where H1 is the thickness of the first plate 222, H2 is the thickness of the second plate 38, L1 is the width of the first groove 60b, and L2 is the width of the second groove 60c.

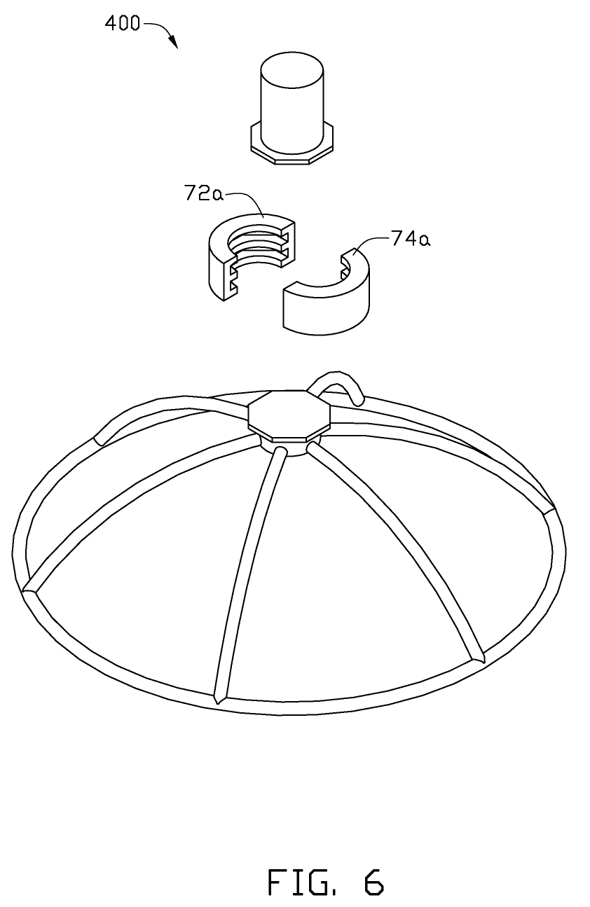

Referring to FIG. 6 together with FIG. 5, a vacuum vapor-deposition apparatus 400 according to a second exemplary embodiment is shown. The difference between the vacuum vapor-deposition apparatus 400 of this embodiment and the vacuum vapor-deposition apparatus 300 of the third embodiment are that the hinge structure 64 is omitted and two additional magnets (not shown) are mounted to the first end 72a and the third end 74a respectively so that the first end 72a is attracted by the third end 74a.

Advantages of the second to fourth embodiments are similar to those of the first embodiment.

It is to be understood, however, that even though numerous characteristics and advantages of the present embodiments have been set fourth in the foregoing description, together with details of the structures and functions of the embodiments, the disclosure is illustrative only, and changes may be made in details, especially in matters of shape, size, and arrangement of parts within the principles of the invention to the full extent indicated by the broad general meaning of the terms in which the appended claims are expressed.

What is claimed is:

1. A vacuum vapor-deposition apparatus for coating a plurality of substrates, comprising:
a motor comprising a rotating shaft, the rotating shaft comprising a first plate fixedly mounted to an end surface of the rotating shaft;
a supporting member configured for mounting the plurality of substrates thereon, the supporting member comprising a second plate corresponding to the first plate;
a connecting ring defining a groove along an inner circumference of the connecting ring, the connecting ring comprising a first semi-ring and a second semi-ring fastened to the first semi-ring, the first plate and the second plate non-rotatably received in the groove, the first plate and the second plate disengageable from the groove if the first and second semi-rings are unfastened; and
a vapor source configured for producing evaporated material to be deposited on the plurality of substrates.

2. The vacuum vapor-deposition apparatus as claimed in claim 1, wherein the supporting member is umbrella-like, the supporting member comprises an umbrella-like supporting body, a connecting body positioned in the top center of the supporting body, and a second plate fixed on an end surface of the connecting body, the umbrella-like supporting body comprises a plurality of spokes radially extending from the connecting body, and an annular member, each spoke has a first end attached to the connecting body and an opposing second end attached to the annular member.

3. The vacuum vapor-deposition apparatus as claimed in claim 1, wherein the first plate has an approximately polygonal cross-section.

4. The vacuum vapor-deposition apparatus as claimed in claim 1, wherein the second plate has an approximately polygonal cross-section.

5. The vacuum vapor-deposition apparatus as claimed in claim 1, wherein the first semi-ring comprises a first end and a second end, the second semi-ring comprises a third end and a fourth end, the first end is hinged to the third end, the second end is magnetically attached to the fourth end.

6. The vacuum vapor-deposition apparatus as claimed in claim 1, wherein the first semi-ring comprises a first end and a second end, the second semi-ring comprises a third end and a fourth end, the first end is magnetically attached to the third end, the second end is magnetically attached to the fourth end.

7. The vacuum vapor-deposition apparatus as claimed in claim 1, further comprising a vacuum container, wherein the motor is positioned on the top of the vacuum container and the rotating shaft extends through the vacuum container.

8. The vacuum vapor-deposition apparatus as claimed in claim 7, wherein the vapor source is positioned on the bottom of the vacuum container facing the supporting member.

9. The vacuum vapor-deposition apparatus as claimed in claim 7, further comprising a controller, wherein a vacuum pump is positioned outside the vacuum container, the controller is electrically connected to the vacuum pump and the motor, the controller is configured for controlling the motor and the vacuum pump.

10. The vacuum vapor-deposition apparatus as claimed in claim 1, the width of the groove equals to or exceeds the sum of the thickness of the first plate and the thickness of the second plate.

11. A vacuum vapor-deposition apparatus for coating a plurality of substrates, comprising:
a motor comprising a rotating shaft, the rotating shaft comprising a first plate fixedly mounted to an end surface of the rotating shaft;
a supporting member configured for mounting the plurality of substrates thereon, the supporting member comprising a second plate;
a connecting ring defining a first groove and a second groove along an inner circumference of the connecting ring, the connecting ring comprising a first semi-ring and a second semi-ring fastened to the first semi-ring, the first plate and the second plate non-rotatably received in the first groove and the second groove respectively, and the first plate and the second plate respectively disengageable from the first groove and the second groove if the first and second semi-rings are unfastened; and
a vapor source configured for producing evaporated material to be deposited on the plurality of substrates.

12. The vacuum vapor-deposition apparatus as claimed in claim 11, wherein the supporting member is umbrella-like, the supporting member comprises an umbrella-like supporting body, a connecting body positioned in the top center of the supporting body, and a second plate fixed on an end surface of the connecting body, the umbrella-like supporting body comprises a plurality of spokes radially extending from the connecting body, and an annular member, each spoke has a first end attached to the connecting body and an opposing second end attached to the annular member.

13. The vacuum vapor-deposition apparatus as claimed in claim 11, wherein the first plate has an approximately polygonal cross-section.

14. The vacuum vapor-deposition apparatus as claimed in claim 11, wherein the second plate has an approximately polygonal cross-section.

15. The vacuum vapor-deposition apparatus as claimed in claim 11, wherein the first semi-ring comprises a first end and a second end, the second semi-ring comprises a third end and a fourth end, the first end is hinged to the third end, the second end is magnetically attached to the fourth end.

16. The vacuum vapor-deposition apparatus as claimed in claim 11, wherein the first semi-ring comprises a first end and a second end, the second semi-ring comprises a third end and a fourth end, the first end is magnetically attached to the third end, the second end is magnetically attached to the fourth end.

17. The vacuum vapor-deposition apparatus as claimed in claim 11, further comprising a vacuum container, wherein the motor is positioned on the top of the vacuum container and the rotating shaft extends through the vacuum container.

18. The vacuum vapor-deposition apparatus as claimed in claim 17, wherein the vapor source is positioned on the bottom of the vacuum container facing the supporting member.

19. The vacuum vapor-deposition apparatus as claimed in claim 17, further comprising a controller, wherein a vacuum pump is positioned outside of the vacuum container, the controller is electrically connected to the vacuum pump and the motor, the controller is configured for controlling the motor and the vacuum pump.

20. The vacuum vapor-deposition apparatus as claimed in claim 11, wherein the width of the first groove equals to or exceeds the thickness of the first plate, the width of the second groove equals to or exceeds the thickness of the second plate.
